(19) United States
(12) Patent Application Publication
(10) Pub. No.: US 2011/0100454 A1
(43) Pub. Date: May 5, 2011

(54) Coated and Planarised Polymeric Films

(75) Inventors: Raymond Adam, Howaldl (LU); Robert W. Eveson, Cleveland (GB); William A. MacDonald, North Yorkshire (GB)

(73) Assignee: Dupont Teijin Films U.S. Limited Partnership, Chester, VA (US)

(21) Appl. No.: 12/988,182

(22) PCT Filed: Apr. 17, 2009
(86) PCT No.: PCT/GB2009/001003

§ 371 Date: Jan. 21, 2011

(30) Foreign Application Priority Data
Apr. 17, 2008 (GB) 0807037.7

(51) Int. Cl. B32B 3/00; B32B 5/16; B32B 17/04; B32B 27/36; B32B 27/08; B32B 5/00; H01L 31/0216; C23C 16/44

(52) U.S. Cl. 136/256; 428/480; 428/323; 428/430; 428/483; 428/447; 428/336; 427/255.28

(57) ABSTRACT

A composite film comprising a polymeric substrate and a planarising coating layer wherein the surface of the planarised substrate exhibits an Ra value of less than 0.7 run and/or an Rq value of less than 0.9 nm, and wherein the composite film further comprises a gas-permeation barrier deposited by atomic layer deposition on a planarised surface of the substrate; an electronic device comprising said composite film; and processes for the production thereof.

The present application concerns polymeric films suitable for use as substrates and/or encapsulant layers in electronic or opto-electronic devices.

Electronic and opto-electronic devices include electroluminescent (EL) display devices (particularly organic light emitting display (OLED) devices), electrophoretic displays (e-paper), photovoltaic cells and semiconductor devices (such as organic field effect transistors, thin film transistors and integrated circuits generally). The present invention is directed to flexible polymeric films which are the insulating and supporting substrates, and/or encapsulant layers, used in these devices. The electronic circuitry which drives the electronic operation of the device is manufactured and/or mounted on the substrate. The component which comprises the substrate and circuitry is often described as a backplane. An encapsulant layer may be disposed on the outside of the device, partially or completely enclosing the circuitry and substrate.

The substrates and encapsulant layers can be transparent, translucent or opaque, but are typically transparent, and they may need to meet stringent specifications for optical clarity, flatness and minimal birefringence. Typically a total light transmission (TLT) of 85% over 400-800 nm coupled with a haze of less than 0.7% is desirable for displays applications. Surface smoothness and flatness are necessary to ensure the integrity of subsequently applied coatings such as the electrode conductive coating. The substrates and encapsulant layers should also have good barrier properties, i.e. high resistance to gas and solvent permeation. Mechanical properties such as flexibility, impact resistance, weight, hardness and scratch resistance are also important considerations. Flexible polymeric substrates and encapsulant layers allow the manufacture of electronic and opto-electronic devices in a reel-to-reel process, thereby reducing cost.

Disadvantages of polymeric materials as substrates and/or encapsulant layers in this technical field include lower chemical resistance, inferior barrier properties and inferior dimensional stability, relative to optical-quality glass or quartz. Inorganic as well as organic barrier coatings have been developed to minimise this problem, and typically these are applied in a sputtering process at elevated temperatures. U.S. Pat. No. 6,198,217 discloses materials suitable as barrier layers. WO-03/022575-A discloses flexible polymeric films which exhibit good high-temperature dimensional stability during the elevated-temperature processing conditions experienced during the manufacture of backplanes and display devices, including deposition of a barrier layer onto a polymeric substrate.

In order to ensure the integrity of the barrier layer, as well as the subsequently applied conductive layers, and to prevent “pin-holes” therein, the surface of a polymeric film must exhibit good smoothness and flatness. WO-03/087247-A teaches planarising coating compositions which achieve this objective. An alternative method for the prevention of pin-holes in the barrier layer, and to ensure the integrity of subsequently applied layers, is the use of atomic layer deposition (ALD) techniques as is known in the art. In the ALD technique, the sequential introduction of reactants and their monolayer self-limiting surface adsorption force a layer-by-layer film growth, which is highly conformable over a textured surface and which thereby prevents pin-holing of the bather layer. Carcia et al. (Appl. Phys. Lett. 89, 031915 (2006); and WO-2004/105149-A) teach that ALD is capable of producing high-performance gas diffusion barrier coatings which eliminate pinholes.

It is an object of this invention to provide a polymeric film which exhibits good gas barrier properties and which is suitable for use as a substrate and/or encapsulant layer in the manufacture of an electronic device, particularly a flexible electronic device, preferably an electronic display, photovoltaic cell or semiconductor device

According to the present invention, there is provided a composite film comprising a polymeric substrate and a planarising coating layer wherein the surface of the planarised substrate exhibits an Ra value of less than 0.7 nm and/or an Rq value of less than 0.9 nm, and wherein the composite film further comprises a gas permeation bather deposited by atomic layer deposition on a planarised surface of the substrate.

The polymeric material of the substrate is preferably polyester. The term polyester as used herein includes a polyester homopolymer in its simplest form or modified, chemically and/or physically. In particular, the polyester is derived from:
(i) one or more diol(s);
(ii) one or more aromatic dicarboxylic acid(s); and
(iii) optionally, one or more aliphatic dicarboxylic acid(s) of the general formula CₙH₂ₙ(COOH)₂ wherein n is 2 to 8,

wherein the aromatic dicarboxylic acid is present in the (co)polyester in an amount of from about 80 to about 100 mole % based on the total amount of dicarboxylic acid components in the (co)polyester. A copolyester may be a random, alternating or block copolyester.

The polyester is obtainable by condensing said dicarboxylic acids or their lower alkyl (up to 6 carbon atoms) diesters with one or more diols. The aromatic dicarboxylic acid is preferably selected from terephthalic acid, isophathalic acid, phthalic acid, 2,5-, 2,6- or 2,7-naphthalenedicarboxylic acid, and is preferably terephthalic acid or 2,6-naphthalenedicarboxylic acid, preferably 2,6-naphthalenedicarboxylic acid. The diol is preferably selected from aliphatic and cycloaliphatic glycols, e.g. ethylene glycol, 1,3-propanediol, 1,4-butanediol, neopentyl glycol and 1,4-cyclohexanedimethanol, preferably from aliphatic glycols. Preferably the copolyester contains only one glycol, preferably ethylene glycol. The aliphatic dicarboxylic acid may be succinic acid, glutaric acid, adipic acid, pimelic acid, suberic acid, azeleic acid or sebacic acid. Preferred homopolyesters are polyesters of 2,6-naphthalenedicarboxylic acid or terephthalic acid with ethylene glycol. A particularly preferred homopolyester is poly(ethylene naphthalate), and particularly polyesters of 2,6-naphthalenedicarboxylic acid with ethylene glycol.

Formation of the polyester is conveniently effected in a known manner by condensation or ester interchange, generally at temperatures up to about 295° C. For instance, the preferred PEN polyester can be synthesised by condensing 2,5-, 2,6- or 2,7-naphthalenedicarboxylic acid, preferably 2,6-naphthalenedicarboxylic acid, or a lower alkyl (up to 6 carbon atoms) diester thereof, with ethylene glycol. Typically, polycondensation includes a solid phase polymerisation stage. The solid phase polymerisation may be carried out on a fluidised bed, e.g. fluidised with nitrogen, or on a vacuum fluidised bed, using a rotary vacuum drier. Suitable solid phase polymerisation techniques are disclosed in, for example, EP-A-0419400 the disclosure of which is incorporated herein by reference. In one embodiment, the PEN is prepared using germanium catalysts which provide a polymeric material having a reduced level of contaminants such as catalyst residues, undesirable inorganic deposits and other byproducts of the polymer manufacture. The “cleaner” polymeric composition promotes improved optical clarity and surface smoothness. Preferably, PEN has a PET-equivalent intrinsic viscosity (IV) of 0.5-1.5, preferably 0.7-1.5, and in particular 0.79-1.0. An IV of less than 0.5 results in a polymeric film lacking desired properties such as mechanical properties whereas an IV of greater than 1.5 is difficult to achieve and would likely lead to processing difficulties of the raw material.

The Tg of a preferred homopolyester, PEN, is generally acknowledged to be 120° C., while that of the other preferred homopolyester, PET, is generally acknowledged to be 80° C. Copolyesters can exhibit Tg values either below or above those of the parent homopolymer depending on the nature of the comonomer which is incorporated. A film made from the polyester may exhibit Tg values higher than that of the polyester raw material, depending on the crystallinity of the film. Thus, as the crystallinity of the film increases, the polyester chains in the amorphous regions of the film become more restricted in their movement, meaning that the glass transition is observed at higher temperatures.

The substrate is self-supporting by which is meant capable of independent existence in the absence of a supporting base. The thickness of the substrate layer is preferably from about 12 to about 250 μm, more preferably from about 12 to about 150 μm, and typically is about 25-125 μm in thickness.

Formation of the substrate layer may be effected by conventional techniques well-known in the art. Conveniently, formation of the substrate is effected by extrusion, in accordance with the procedure described below. In general terms the process comprises the steps of extruding a layer of molten polymer, quenching the extrudate and orienting the quenched extrudate in at least one direction.

The substrate is preferably biaxially-oriented. Orientation may be effected by any process known in the art for producing an oriented film, for example a tubular or flat film process. Biaxial orientation is effected by drawing in two mutually perpendicular directions in the plane of the film to achieve a satisfactory combination of mechanical and physical properties.

In a tubular process, simultaneous biaxial orientation may be effected by extruding a thermoplastics polyester tube which is subsequently quenched, reheated and then expanded by internal gas pressure to induce transverse orientation, and withdrawn at a rate which will induce longitudinal orientation.

In the preferred flat-film process, the film-forming polyester is extruded through a slot die and rapidly quenched upon a chilled casting drum to ensure that the polyester is quenched to the amorphous state. Orientation is then effected by stretching the quenched extrudate in at least one direction at a temperature above the glass transition temperature of the polyester. Sequential orientation may be effected by stretching a flat, quenched extrudate firstly in one direction, usually the longitudinal direction, i.e. the forward direction through the film-stretching machine, and then in the transverse direction. Forward stretching of the extrudate is conveniently effected over a set of rotating rolls or between two pairs of nip rolls, transverse stretching then being effected in a stenter apparatus. Stretching is generally effected so that the dimension of the oriented film is from 2 to 5, more preferably 2.5 to 4.5 times its original dimension in the or each direction of stretching. Typically, stretching is effected at temperatures higher than the Tg of the polyester, preferably about 15° C. higher than the Tg. Greater draw ratios (for example, up to about 8 times) may be used if orientation in only one direction is required. It is not necessary to stretch equally in the machine and transverse directions although this is preferred if balanced properties are desired.

A stretched film may be, and preferably is, dimensionally stabilised by heat-setting under dimensional support at a temperature above the glass transition temperature of the polyester but below the melting temperature thereof, to induce crystallisation of the polyester. During the heat-setting, a small amount of dimensional relaxation may be performed in the transverse direction, TD by a procedure known as “toe-in”. Toe-in can involve dimensional shrinkage of the order 2 to 4% but an analogous dimensional relaxation in the process or machine direction, MD is difficult to achieve since low line tensions are required and film control and winding becomes problematic. The actual heat-set temperature and time will vary depending on the composition of the film and its desired final thermal shrinkage but should not be selected so as to substantially degrade the toughness properties of the film such as tear resistance. Within these constraints, a heat set temperature of about 180° to 245° C. is generally desirable.

The substrate may also, and indeed preferably is, further stabilized through use of an online relaxation stage. Alternatively the relaxation treatment can be performed off-line. In this additional step, the film is heated at a temperature lower than that of the heat-setting stage, and with a much reduced MD and TD tension. Film thus processed will exhibit a smaller thermal shrinkage than that produced in the absence of such post heat-setting relaxation.

In one embodiment, heat-setting and heat-stabilisation of the biaxially stretched film is conducted as follows. After the stretching steps have been completed, heat-setting is effected by dimensionally restraining the film at a tension in the range of about 19 to about 75 kg/m of film width, and in one embodiment from about 45 to about 50 kg/m of film width, using a heat-set temperature preferably from about 135° to about 250° C., more preferably 235-240° C. and a heating duration typically in the range of 5 to 40 secs, preferably 8 to 30 seconds. The heat-set film is then heat-stabilised by heating it under low tension, preferably such that the tension experienced by the film is less than 10 kg/m of film width, in one embodiment less than 5 kg/m, and in a further embodiment in the range of from 1 to about 3.5 kg/m of film width, typically using a temperature lower than that used for the heat-setting step and selected to be in the range of from about 135° C. to 250° C., preferably 150 to 230° C., and for a duration of heating typically in the range of 5 to 40 sec, and in one embodiment with a duration of 20 to 30 seconds. In one embodiment particularly applicable to PET, the heat-set film is heat-stabilised using a temperature in the range of from about 140 to 190° C., preferably 150 to 180° C. In one embodiment particularly applicable to PEN, the heat-set film is heat-stabilised using a temperature in the range of from about 170 to 230° C., preferably 180 to 210° C.

A heat-set, heat-stabilised substrate exhibits a very low residual shrinkage and consequently high dimensional stability.

Preferably, the substrate exhibits a coefficient of linear thermal expansion (CLTE) within the temperature range from 23° C. to the glass transition temperature (Tg (° C.)) of the substrate of less than 40×10⁻⁶/° C., preferably less than 30×10⁻⁶/° C., preferably less than 25×10⁻⁶/° C., preferably less than 20×10⁻⁶/° C., more preferably less than 15×10⁻⁶/° C. in each of the machine and transverse dimensions. In one embodiment, a PEN substrate has a CLTE within the temperature range from 23° C. to +120° C. of less than 40×10⁻⁶/° C., preferably less than 30×10⁻⁶/° C., preferably less than 25×10⁻⁶/° C., more preferably less than 20×10⁻⁶/° C., more preferably less than 15×10⁻⁶/° C. For a PET substrate, the CLTE within the temperature range from 23° C. to +80° C. is preferably less than 40×10⁻⁶/° C., preferably less than 30×10⁻⁶/° C., preferably less than 25×10⁻⁶/° C., preferably less than 20×10⁻⁶/° C., more preferably less than 15×10⁻⁶/° C.

In one embodiment, the substrate has a shrinkage at 30 mins at 150° C., measured as defined herein, of no more than 0.5%, preferably no more than 0.25%, preferably no more than 0.1%, preferably no more than 0.05%, and more preferably no more than 0.03%, in each of the machine and transverse dimensions. Preferably, the substrate (particularly a heat-stabilised, heat-set, biaxially oriented PEN substrate) has a shrinkage at 10 mins at 200° C., measured as defined herein, of no more than 2%, preferably no more than 1%, preferably no more than 0.75%, preferably no more than 0.5%, preferably no more than 0.25%, and more preferably no more than 0.1% in each of the machine and transverse dimensions. In one embodiment, the substrate (particularly a heat-stabilised, heat-set, biaxially oriented PET substrate) has a shrinkage at 30 mins at 120° C., measured as defined herein, of no more than 0.5%, preferably no more than 0.25%, preferably no more than 0.1%, and more preferably no more than 0.05%, in each of the machine and transverse dimensions. In a preferred embodiment, a heat-stabilised, heat-set, biaxially oriented PET substrate has a shrinkage at 30 mins at 150° C., measured as defined herein, of no more than 0.5%, preferably no more than 0.25%, preferably no more than 0.1%, preferably no more than 0.05%, and more preferably no more than 0.03%, in each of the machine and transverse dimensions.

In a particularly preferred embodiment, the substrate is a heat-stabilised, heat-set biaxially oriented film comprising poly(ethylene naphthalate) having the afore-mentioned shrinkage characteristics after 10 min at 200° C., and preferably having the afore-mentioned CLTE characteristics.

The substrate may conveniently contain any of the additives conventionally employed in the manufacture of polyester films and which are known not to migrate out of the film, to its surface. The additive will not therefore contaminate the surface of the film during annealing and not contribute to the observed effect of surface haze. Thus, agents such as cross-linking agents, pigments and voiding agents, agents such as anti-oxidants, radical scavengers, UV absorbers, thermal stabilisers, flame retardants and inhibitors, which are solid, or bound covalently to the polyester and finally agents which are stable, non-migrating optical brighteners, gloss improvers, prodegradents, viscosity modifiers and dispersion stabilisers may be incorporated as appropriate. In particular, the substrate may comprise a particulate filler which can improve handling and windability during manufacture. The particulate filler may, for example, be a particulate inorganic filler (e.g. voiding or non-voiding metal or metalloid oxides, such as alumina, silica and titania, calcined china clay and alkaline metal salts, such as the carbonates and sulphates of calcium and barium), or an incompatible resin filler (e.g. polyamides and olefin polymers, particularly a homo- or co-polymer of a mono-alpha-olefin containing up to 6 carbon atoms in its molecule) or a mixture of two or more such fillers.

The components of the composition of a layer may be mixed together in a conventional manner. For example, by mixing with the monomeric reactants from which the film-forming polyester is derived, or the components may be mixed with the polyester by tumble or dry blending or by compounding in an extruder, followed by cooling and, usually, comminution into granules or chips. Masterbatching technology may also be employed.

In a preferred embodiment, the substrate is optically clear, preferably having a % of scattered visible light (haze) of <10%, preferably <6%, more preferably <3.5% and particularly <1.5%, measured according to the standard ASTM D 1003. In this embodiment, filler is typically present in only small amounts, generally not exceeding 0.5% and preferably less than 0.2% by weight of a given layer.

The exposed surface of the film substrate may, if desired, be subjected to a chemical or physical surface-modifying treatment to improve the bond between that surface and a subsequently applied layer. A preferred treatment, because of its simplicity and effectiveness, is to subject the exposed surface of the film to a high voltage electrical stress accompanied by corona discharge. The preferred treatment by corona discharge may be effected in air at atmospheric pressure with conventional equipment using a high frequency, high voltage generator, preferably having a power output of from 1 to 20 kW at a potential of 1 to 100 kV. Discharge is conventionally accomplished by passing the film over a dielectric support roller at the discharge station at a linear speed preferably of 1.0 to 500 m per minute. The discharge electrodes may be positioned 0.1 to 10.0 mm from the moving film surface.

Prior to application of the planarising coating, the substrate is preferably coated with a primer layer to improve adhesion of the substrate to the planarising coating composition. The primer layer may be any suitable adhesion-promoting polymeric composition known in the art, including polyester and acrylic resins. The primer composition may also be a mixture of a polyester resin with an acrylic resin. Acrylic resins may optionally comprise oxazoline groups and polyalkylene oxide chains. The polymer(s) of the primer composition is/are preferably water-soluble or water-dispersible.

Polyester primer components include those obtained from the following dicarboxylic acids and diols. Suitable di-acids include terephthalic acid, isophthalic acid, phthalic acid, phthalic anhydride, 2,6-naphthalenedicarboxylic acid, 1,4-cyclohexanedicarboxylic acid, adipic acid, sebacic acid, trimellitic acid, pyromellitic acid, a dimer acid, and 5-sodium sulfoisophthalic acid. A copolyester using two or more dicarboxylic acid components is preferred. The polyester may optionally contain a minor amount of an unsaturated di-acid component such as maleic acid or itaconic acid or a small amount of a hydroxycarboxylic acid component such as p-hydroxybenzoic acid. Suitable diols include ethylene glycol, 1,4-butanediol, diethylene glycol, dipropylene glycol, 1,6-hexanediol, 1,4-cyclohexanedimethylol, xylene glycol, dimethylolpropane, poly(ethylene oxide) glycol, and poly(tetramethylene oxide) glycol. The glass transition point of the polyester is preferably 40 to 100° C., further preferably 60 to 80° C. Suitable polyesters include copolyesters of PET or PEN with relatively minor amounts of one or more other dicarboxylic acid comonomers, particularly aromatic di-acids such as isophthalic acid and sodium sulphoisophthalic acid, and optionally relatively minor amounts of one or more glycols other than ethylene glycol, such as diethylene glycol.

In one embodiment, the primer layer comprises an acrylate or methacrylate polymer resin. The acrylic resin may comprise one or more other comonomers. Suitable comonomers include alkyl acrylates, alkyl methacrylates (where the alkyl group is preferably methyl, ethyl, n-propyl, isopropyl, n-butyl, isobutyl, t-butyl, 2-ethylhexyl, cyclohexyl or the like); hydroxy-containing monomers such as 2-hydroxyethyl acrylate, 2-hydroxyethyl methacrylate, 2-hydroxypropyl acrylate, and 2-hydroxypropyl methacrylate; epoxy group-containing monomers such as glycidyl acrylate, glycidyl methacrylate, and allyl glycidyl ether; carboxyl group or its salt-containing monomers, such as acrylic acid, methacrylic acid, itaconic acid, maleic acid, fumaric acid, crotonic acid, styrenesulfonic acid and their salts (sodium salt, potassium salt, ammonium salt, quaternary amine salt or the like); amide group-containing monomers such as acrylamide, methacrylamide, an N-alkylacrylamide, an N-alkylmethacrylamide, an N,N-dialkylacrylamide, an N,N-dialkyl methacrylate (where the alkyl group is preferably selected from those described above), an N-alkoxyacrylamide, an N-alkoxymethacrylamide, an N,N-dialkoxyacrylamide, an N,N-dialkoxymethacrylamide (the alkoxy group is preferably methoxy, ethoxy, butoxy, isobutoxy or the like), acryloylmorpholine, N-methylolacrylamide, N-methylolmethacrylamide, N-phenylacrylamide, and N-phenylmethacrylamide; acid anhydrides such as maleic anhydride and itaconic anhydride; vinyl isocyanate, allyl isocyanate, styrene, α-methylstyrene, vinyl methyl ether, vinyl ethyl ether, a vinyltrialkoxysilane, a monoalkyl maleate, a monoalkyl fumarate, a monoalkyl itaconate, acrylonitrile, methacrylonitrile, vinylidene chloride, ethylene, propylene, vinyl chloride, vinyl acetate, and butadiene. In a preferred embodiment, the acrylic resin is copolymerised with one or more monomer(s) containing oxazoline groups and polyalkylene oxide chains. The oxazoline group-containing monomer includes 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, and 2-isopropenyl-5-methyl-2-oxazoline. One or more comonomers may be used. 2-Isopropenyl-2-oxazoline is preferred. The polyalkylene oxide chain-containing monomer includes a monomer obtained by adding a polyalkylene oxide to the ester portion of acrylic acid or methacrylic acid. The polyalkylene oxide chain includes polymethylene oxide, polyethylene oxide, polypropylene oxide, and polybutylene oxide. It is preferable that the repeating units of the polyalkylene oxide chain are 3 to 100.

Where the primer composition comprises a mixture of polyester and acrylic components, particularly an acrylic resin comprising oxazoline groups and polyalkylene oxide chains, it is preferable that the content of the polyester is 5 to 95% by weight, preferably 50 to 90% by weight, and the content of the acrylic resin is 5 to 90% by weight, preferably 10 to 50% by weight.

Other suitable acrylic resins include:

(i) a copolymer of (a) 35 to 40 mole % alkyl acrylate, (b) 35 to 40% alkyl methacrylate, (c) 10 to 15 mole % of a comonomer containing a free carboxyl group such as itaconic acid, and (d) 15 to 20 mole % of an aromatic sulphonic acid and/or salt thereof such as p-styrene sulphonic acid, an example of which is a copolymer comprising ethyl acrylate/methyl methacrylate/itaconic acid/p-styrene sulphonic acid and/or a salt thereof in a ratio of 37.5/37.5/10/15 mole %, as disclosed in EP-A-0429179 the disclosure of which is incorporated herein by reference; and

(ii) an acrylic and/or methacrylic polymeric resin, an example of which is a polymer comprising about 35 to 60 mole % ethyl acrylate, about 30 to 55 mole % methyl methacrylate and about 2 to 20 mole % methacrylamide, as disclosed in EP-A-0408197 the disclosure of which is incorporated herein by reference.

The primer or adherent layer may also comprise a cross-linking agent which improves adhesion to the substrate and should also be capable of internal cross-linking. Suitable cross-linking agents include optionally alkoxylated condensation products of melamine with formaldehyde. The primer or adherent layer may also comprise a cross-linking catalyst, such as ammonium sulphate, to facilitate the cross-linking of the cross-linking agent. Other suitable cross-linking agents and catalysts are disclosed in EP-A-0429179, the disclosures of which are incorporated herein by reference.

A further suitable primer is disclosed in U.S. Pat. No. 3,443,950, the disclosure of which is incorporated herein by reference.

The coating of the primer layer onto the substrate may be performed in-line or off-line, but is preferably performed “in-line”, and preferably between the forward and sideways stretches of a biaxial stretching operation.

The planarising coating layer may be disposed on one or both surfaces of the optionally-primed substrate. In one embodiment, the coating is present on both sides of the optionally-primed substrate. The planarising coating layers fall broadly into one of the three following classifications: organic, organic/inorganic hybrid and predominantly inorganic coats.

An organic planarising coating composition typically comprises: (i) a photoinitiator; (ii) a low molecular weight reactive diluent (e.g a monomeric acrylate); (iii) an unsaturated oligomer (e.g, acrylates, urethane acrylates, polyether acrylates, epoxy acrylates or polyester acrylates); and (iv) a solvent. Such organic coatings can be cured by free radical reaction, initiated by a photolytic route. Specific formulations may vary according to the desired final properties. In one embodiment, the organic planarising coating composition comprises a UV-curable mixture of monomeric and oligomeric acrylates (preferably comprising methylmethacrylate and ethylacrytate) in a solvent (such as methylethylketone), typically wherein the coating composition comprises the acrylates at about 20 to 30 wt % solids of the total weight of the composition, and further comprising a minor amount (e.g. about 1% by weight of the solids) of photoinitiator (e.g. Irgacure™ 2959; Ciba).

As used herein, the term “low molecular weight” describes a polymerisable monomeric species. The term “reactive” signifies the polymerisability of the monomeric species.

In a further embodiment, an organic planarising coating composition comprises a cross-linkable organic polymer, for instance a polyethylene imine (PEI), polyester, polyvinylalcohol (PVOH), polyimide, polythiol or polyacrylic acid, and a cross-linking agent (such as Cymel™ 385 or those referred to herein), in a solvent (typically an aqueous solvent). In this embodiment, the coating composition preferably comprises PEI (preferably with a molecular weight (Mw) in the range 600,000 to 900,000).

An organic/inorganic hybrid coating comprises inorganic particles distributed throughout an organic polymeric matrix. Thus, the organic component typically comprises a low molecular weight reactive component (e.g. monomeric acrylates) and/or an unsaturated oligomeric component (e.g. acrylates, urethane acrylates, polyether acrylates, epoxy acrylates and polyester acrylates). The coatings are cured either thermally or by free-radical reaction initiated by a photolytic route. The presence of a photoinitiator in the coating composition is therefore optional. A solvent is typically present in the coating composition. The inorganic particles are typically silica or metal oxides, more typically silica, dispersed in the polymerisable organic matrix. The inorganic particles preferably have an average particle diameter of 0.005 to 3 μm; in one embodiment at least 0.01 μm, and in one embodiment no more than 1 μm. The inorganic particles are typically selected so as not to substantially affect the optical properties of the substrate or composite film. In one embodiment, the inorganic particles are present in an amount of from about 5% to about 60% by weight of the solids components of the coating composition, and preferably from about 5% to about 60% by weight of the cured coating layer.

Thus, in one embodiment, the organic/inorganic hybrid coating composition comprises a low molecular weight reactive component (e.g. monomeric acrylates) and/or an unsaturated oligomeric component (e.g. acrylates, urethane acrylates, polyether acrylates, epoxy acrylates and polyester acrylates), inorganic particles preferably selected from silica and metal oxides, a solvent, and optionally a photoinitiator.

In a further embodiment, a thermally-curable organic/inorganic hybrid coating composition comprises an epoxy resin in combination with inorganic (preferably silica) particles which are preferably present at a concentration of at least about 10% (preferably at least about 20%, and preferably no more than about 75%) by weight of the solids of the coating composition (which preferably comprises from 5 to about 20% by weight total solids in alcoholic solution).

In a further embodiment, a UV-curable organic/inorganic hybrid coating composition comprises monomeric acrylates (typically multi-functional acrylates) in combination with inorganic (preferably silica) particles in a solvent (such as methylethylketone), typically wherein the coating composition comprises the acrylates and silica at about 5 to 50 wt % solids of the total weight of the coating composition, and typically further comprising a minor amount (e.g. about 1% by weight of the solids) of photoinitiator. Multi-functional monomeric acrylates are known in the art, and examples include dipentaerythritol tetraacrylate and tris(2-acryloyloxyethyl)iso cyanurate.

A predominantly inorganic planarising coating composition comprises inorganic particles which are contained in a polymerisable predominantly inorganic matrix such as a polysiloxane, and such coating compositions are typically cured thermally. In one embodiment, an inorganic coating is derived from a coating composition comprising:

(a) from about 5 to about 50 weight percent solids, the solids comprising from about 10 to about 70 weight percent (preferably from about 20 to 60 wt %) silica and from about 90 to about 30 weight percent of a partially polymerized organic silanol of the general formula RSi(OH)₃, wherein R is selected from methyl and up to about 40% of a group selected from the group consisting of vinyl, phenyl, gamma-glycidoxypropyl, and gamma-methacryloxypropyl, and

(b) from about 95 to about 50 weight percent solvent, the solvent comprising from about 10 to about 90 weight percent water and from about 90 to about 10 weight percent lower aliphatic alcohol,

particularly wherein the coating composition has a pH of from about 3.0 to about 8.0, preferably from about 3.0 to about 6.5, preferably at least 4.0.

The silica component of this predominantly inorganic coating composition may be obtained, for example, by the hydrolysis of tetraethyl orthosilicate to form polysilicic acid. The hydrolysis can be carried out using conventional procedures, for example, by the addition of an aliphatic alcohol and an acid. Alternatively, the silica used in the coating compositions can be colloidal silica. The colloidal silica should generally have a particle size of about from 5-25 nm, and preferably about from 7-15 nm. Typical colloidal silicas which can be used include those commercially available as “Ludox SM”, “Ludox HS-30” and “Ludox LS” dispersions (Grace Davison). The organic silanol component has the general formula RSi(OH)₃. At least about 60% of the R groups, and preferably about from 80% to 100% of these groups, are methyl. Up to about 40% of the R groups can be higher alkyl or aryl selected from vinyl, phenyl, gamma-glycidoxypropyl, and gamma-methacryloxypropyl. The solvent component generally comprises a mixture of water and one or more lower aliphatic alcohols. The water generally comprises about from 10 to 90 weight percent of the solvent, while the lower aliphatic alcohol complementarily comprises about from 90 to 10 weight percent. The aliphatic alcohols generally are those having from 1 to 4 carbon atoms, such as methanol, ethanol, n-propanol, iso-propanol, n-butanol, sec-butanol and tertiary butanol.

Other examples of a planarising layer are disclosed in, for instance, U.S. Pat. No. 4,198,465, U.S. Pat. No. 3,708,225, U.S. Pat. No. 4,177,315, U.S. Pat. No. 4,309,319, U.S. Pat. No. 4,436,851, U.S. Pat. No. 4,455,205, U.S. Pat. No. 0,142,362, WO-A-03/087247 and EP 1418197 the disclosures of which are incorporated herein by reference.

The planarising coating compositions can be applied using conventional coating techniques, including continuous as well as dip coating procedures. The coatings are generally applied to provide a dry thickness of from about 1 to about 20 microns, preferably from about 2 to 10 microns, and particularly from about 3 to about 10 microns. The coating composition can be applied either “off-line” as a process step distinct from the film manufacture, or “in-line” as a continuation of the film manufacturing process. The coating is preferably performed in-line.

Thermally-curable coating compositions, after application to the substrate, can be cured at a temperature of from about 20 to about 200° C., preferably from about 20 to about 150° C. While ambient temperatures of 20° C. require cure times of several days, elevated temperatures of 150° C. will cure the coatings in several seconds.

The planarised films exhibit a surface having an Ra value, as measured herein, of less than 0.7 nm, preferably less than 0.6 nm, preferably less than 0.5 nm, preferably less than 0.4 nm, preferably less than 0.3 nm, and ideally less than 0.25 nm, and/or an Rq value, as measured herein, of less than 0.9 nm, preferably less than 0.8 nm, preferably less than 0.75 nm, preferably less than 0.65 nm, preferably less than 0.6 nm, preferably less than 0.50 nm, preferably 0.45 nm or lower, preferably less than 0.35 nm, and ideally less than 0.3 nm.

Prior to deposition of the gas-permeation barrier layer by ALD, the planarised surface may be subjected to a plasma pre-treatment, as described in greater detail in the applicant's co-pending WO-A-2006/097733. Typically, plasma pre-treatment is effected under an atmosphere of argon/nitrogen or argon/oxygen, for a period of between about 2 and 8 minutes, and preferably about 5 minutes. Preferably, the plasma pre-treatment is microwave-activated, i.e. is effected using a microwave plasma source, typically without another plasma source.

The gas-permeation barrier layer is applied to the surface of the planarised substrate, i.e. on the surface of the planarising coating layer. The barrier layer in particular provides barrier properties to water vapour and/or oxygen transmission, particularly such that the water vapour transmission rate is less than 10⁻³ g/m²/day and/or the oxygen transmission rate is less than 10⁻³/mL/m²/day. Preferably, the water vapour transmission rate is less than 10⁻⁴ g/m²/day, preferably less than 10⁻⁵ g/m²/day, preferably less than 10⁻⁶ g/m²/day. Preferably, the oxygen transmission rate is less than 10⁻⁴ g/m²/day, preferably less than 10⁻⁵ g/m²/day. The gas-permeation barrier layer is applied by atomic layer deposition (ALD), which is normally effected in a clean environment. ALD is a self-limiting, sequential surface chemistry that deposits conformal thin films of materials onto a substrate, making atomic scale deposition possible. Films grown by ALD are formed in a layer-wise fashion, and the process allows atomic layer control of film growth as fine as about 0.1 angstroms per mono-layer. The total thickness of the deposited film is typically about 1-500 nm. With ALD it is possible to deposit coatings perfectly uniform in thickness inside deep trenches, porous media and around particles. ALD-grown films are chemically bonded to the substrate. A description of the (ALD) process can be found in, for instance, “Atomic Layer Epitaxy” by Tuomo Suntola in Thin Solid Films, vol. 216 (1992) pp. 84-89. ALD is similar in chemistry to chemical vapor deposition (CVD), except that the ALD reaction breaks the CVD reaction into two half-reactions, keeping the precursor materials separate during the coating process and reaction. In the process, a vapour of the layer precursor is absorbed on a substrate in a vacuum chamber. The vapour is then pumped from the chamber, leaving a thin layer of absorbed precursor on the substrate. A reactant is then introduced into the chamber under thermal conditions, which promote reaction with the absorbed precursor to form a layer of the desired material. Reaction by-products are pumped from the chamber. Subsequent layers of material can be formed by again exposing the substrate to the precursor vapour and repeating the deposition process. ALD has been distinguished from conventional CVD and physical vapour deposition (PVD) methods in which growth is initiated and then proceeds at finite numbers of nucleation sites on the substrate surface. The latter techniques can lead to columnar growth with granular microstructures, exhibiting boundaries between columns along which gas permeation can be facile. The ALD process involves a non-directional growth mechanism to achieve a featureless microstructure.

The materials formed by ALD and suitable as a barrier layer in the present invention are inorganic and include oxides, nitrides and sulphides of Groups IVB, VB, VIB, IIIA, IIB, IVA, VA and VIA of the Periodic Table and combinations thereof. Of particular interest are oxides and nitrides. Materials of particular interest include SiO₂, Al₂O₃, ZnO, ZnS, HfO₂, HfON, AlN, and Si₃N₄. Mixed oxide-nitrides are also of interest. The oxides exhibit optical transparency which is attractive for electronic displays and photovoltaic cells where visible light must either exit or enter the device. The nitrides of Si and Al are also transparent in the visible spectrum.

The precursors used in the ALD process to form these barrier materials are well-known (see for instance M. Leskela and M. Ritala, “ALD precursor chemistry: Evolution and future challenges”, Journal de Physique IV, vol. 9, pp 837-852 (1999) and references therein).

The preferred range of substrate temperature for synthesizing barrier coatings by ALD is 50 to 250° C. Temperatures greater than 250° C. are undesirable since they may cause chemical degradation of the substrate or disruption of the ALD coating because of dimensional change in the substrate.

The thickness of the gas-permeation barrier layer is preferably in the range of 2 nm to 100 nm, more preferably 2 to 50 nm. Thinner layers are more tolerant to flexing without causing the film to crack, which is an important property of flexible substrates in electronic devices since cracking compromises barrier properties. Thinner barrier films are also more transparent, an important characteristic when used in opto-electronic devices. The minimum thickness of the barrier layer is that required for continuous film coverage.

In one embodiment, an adhesion-promoting layer is provided on the substrate immediately prior to the ALD process, although such a layer is not generally required in the present invention particularly when the preferred planarising coating compositions are utilised. The thickness of the optional adhesion-promoting layer is preferably in the range of 1 to 100 nm. The materials suitable as an adhesion-promoting layer are typically selected from the group of barrier materials described above. Aluminum oxide and silicon oxide are preferred for the adhesion-promoting layer, which may also be deposited by ALD, although other methods such as CVD or PVD may also be suitable.

Once the barrier layer has been deposited, subsequent layers, including the electrode and for instance a conductive conjugated polymer layer, may be applied in accordance with conventional manufacturing techniques known in the art.

Thus, in one embodiment, the composite film of the present invention further comprises an electrode layer. The electrode layer may be a layer, or a patterned layer, of a suitable conductive material as known in the art, for instance gold or a conductive metal oxide such as indium tin oxide, optionally doped with other metals as is known in the art. Other materials suitable as for the electrode layer are well-known to the skilled person and include, for instance, silver, aluminium platinum, palladium, nickel. The electrode layer is optionally transparent or translucent. In a preferred embodiment, the electrode layer comprises gold. In one embodiment, a tie layer is deposited on the coated film prior to deposition of the electrode layer. Such a tie-layer typically comprises a metallic layer deposited by conventional techniques onto a surface of the coated film, wherein the metallic layer is different to the conductive material of the electrode layer.

The composite film of the present invention is suitable for use as a substrate and/or encapsulant film for, and in the manufacture of electronic devices, particularly flexible electronic devices, including electronic, photonic and optical assemblies or structures, and preferably electronic display devices (including rollable electronic displays), photovoltaic cells and semiconductor devices, particularly in the manufacture of the backplanes referred to above. In one embodiment, the term “electronic device” as used herein refers to a device which contains as essential features at least a polymeric substrate and electronic circuitry. Electronic and opto-electronic devices may comprise a conductive polymer. Preferably, the device is an electronic display device including, for example, an electroluminescent (EL) device (particularly an organic light emitting display (OLED)), an electrophoretic display (e-paper), a liquid crystal display device or an electrowetting display device; a photovoltaic cell; or a semiconductor device (such as organic field effect transistors, thin film transistors and integrated circuits generally). In one embodiment, the term “electroluminescent display device”, and particularly the term “organic light emitting display (OLED) device”, as used herein refers to a display device comprising a layer of light-emitting electroluminescent material (particularly a conductive polymeric material) disposed between two layers each of which comprises an electrode, wherein the resultant composite structure is disposed between two substrate (or support or cover) layers. In one embodiment, the term “photovoltaic cell” as used herein refers to a device comprising a layer of conductive polymeric material disposed between two layers each of which comprises an electrode, wherein the resultant composite structure is disposed between two substrate (or support or cover) layers. In one embodiment, the term “transistor” as used herein refers to a device comprising at least one layer of conductive polymer, a gate electrode, a source electrode and a drain electrode, and one or more substrate layers.

Thus, according to a further aspect of the invention, there is provided an electronic device, particularly a flexible electronic device, comprising a composite film as defined herein. The device typically further comprises one or more layer(s) of electroluminescent material, two or more electrodes, and one or more substrate layers.

According to a further aspect of the invention, there is provided a process for the manufacture of a composite film which comprises the step of disposing by atomic layer deposition a gas-permeation barrier layer on the or each planarised surface of a planarised coated polymeric substrate, the planarised coated surface of which exhibits an Ra value of less than 0.7 nm, and/or an Rq value of less than 0.9 nm. Preferably, the polymeric substrate is provided by a process comprising the following steps: (a) forming a polymeric substrate layer; (b) stretching the substrate layer in at least one direction; (c) heat-setting under dimensional restraint at a tension in the range of about 19 to about 75 kg/m of film width, at a temperature above the glass transition temperature of the polymer of the substrate layer but below the melting temperature thereof; and (d) heat-stabilising the film at a temperature above the glass transition temperature of the polymer of the substrate layer but below the melting temperature thereof. Preferably, the planarised coated polymeric substrate is provided by disposing on the or each surface of a polymeric substrate a planarising coating composition such that the planarised coated surface of the polymeric substrate exhibits an Ra value of less than 0.7 nm, and/or an Rq value of less than 0.9 nm.

According to a further aspect of the invention, there is provided a process for the manufacture of an electronic device, particularly a flexible electronic device, said process comprising the step of providing a composite film as a substrate and/or encapsulant layer in said electronic device, wherein said composite film comprises a planarised coated polymeric substrate and on the or each planarised surface thereof a gas-permeation barrier layer deposited by atomic-layer deposition.

According to a further aspect of the invention, there is provided a process for the manufacture of a composite film which comprises the steps of

(i) providing a polymeric substrate, preferably comprising the following steps:
(a) forming a polymeric substrate layer;
(b) stretching the substrate layer in at least one direction;
(c) heat-setting under dimensional restraint at a tension in the range of about 19 to about 75 kg/m of film width, at a temperature above the glass transition temperature of the polymer of the substrate layer but below the melting temperature thereof; and
(d) heat-stabilising the film at a temperature above the glass transition temperature of the polymer of the substrate layer but below the melting temperature thereof;

(ii) disposing on the or each surface of the optionally primed substrate a planarising coating composition such that the surface of the planarised coated substrate exhibits an Ra value of less than 0.7 nm, and/or an Rq value of less than 0.9 nm; and

(iii) providing by atomic layer deposition a gas-permeation bather layer on the or each planarised surface of the substrate.

According to a further aspect of the invention, there is provided a process for the manufacture of an electronic device, particularly a flexible electronic device, said process comprising the process steps (i) to (iii) set out in the preceding paragraph, and further comprising the step of

(iv) providing the composite film comprising said planarised polymeric substrate layer and said gas-permeation barrier layer as a substrate and/or encapsulant layer in said electronic device.

The methods of manufacture of the composite film and electronic device described herein may further comprise the step of providing an electrode layer comprising a conductive material, which is typically performed by applying a conductive material onto at least part of the bather layer, in accordance with conventional manufacturing techniques known in the art. A further step in the manufacturing methods described herein is providing a layer of electroluminescent material (e.g. a conductive polymer).

The pre-treatment of the substrate with a planarising coating prior to deposition of a gas-barrier layer by ALD provides a number of advantages. The teaching of the prior art (see, for instance, Carcia et al., supra) is that ALD provides a conformable pinhole-free barrier layer over a textured surface and indeed the prior art teaches that ALD alone achieves that objective. However, the present inventors did not observe this Instead, the present inventors have found that the additional use of a planarising coating prior to deposition of the ALD-layer, and particularly the preferred planarising coatings described herein, unexpectedly provides further improvements in the gas-bather performance of the substrate, which is very surprising given the prior art disclosure. Thus, the present invention resides in the realisation that a certain level of surface smoothness (as defined herein) is required to provide high barrier properties to an ALD-coated substrate, particularly in order to achieve a water vapour transmission rate of less than 10⁻³ g/m²/day and/or an oxygen transmission rate of less than 10⁻³/mL/m²/day. It is believed that the preferred coatings, particularly the preferred planarising coatings described herein, provide a particularly suitable surface environment for the growth of the ALD-deposited layer, particularly when the ALD layer is aluminium oxide, and reduce or eliminate the need for an additional adhesion-promoting inorganic layer as taught in WO-2004/105149-A. By eliminating surface contamination, the presence of the planarising coating also provides a consistent chemistry over the surface of the substrate, rather than simply a smooth surface.

Property Measurement

The following approaches may be used to characterize the film properties:
(i) Thermal shrinkage was assessed for film samples of dimensions 200 mm×10 mm which were cut in specific directions relative to the machine and transverse directions of the film and marked for visual measurement. The longer dimension of the sample (i.e. the 200 mm dimension) corresponds to the film direction for which shrinkage is being tested, i.e. for the assessment of shrinkage in the machine direction, the 200 mm dimension of the test sample is oriented along the machine direction of the film. After heating the specimen to the predetermined temperature (by placing in a heated oven at that temperature) and holding for the pre-determined time interval, it was cooled to room temperature and its dimensions re-measured manually. The thermal shrinkage was calculated and expressed as a percentage of the original length.
(ii) For film samples which were essentially transparent, that is containing sufficiently low levels of additive, pigment, void or other body which would render it opaque, film clarity was evaluated. This was achieved by measuring total luminance transmission (TLT) and haze (% of scattered transmitted visible light) through the total thickness of the film using a Gardner XL 211 hazemeter in accordance with ASTM D-1003-61.
(iii) The glass transition temperature (Tg) of the polyester film was measured using Differential Scanning Calorimetry (DSC) techniques. The measurement was performed using a TA Instruments Q100 DSC System, calibrated using an indium standard. Samples of film were heated from below ambient temperature (approximately −20° C.) to 300° C. and final values of temperature were reported for a heating rate of 20° K/minute.
(iv) Dimensional stability of a film sample as measured by the coefficient of linear thermal expansion (CLTE) is measured as follows. A Thermomechanical Analyser PE-TMA-7 (Perkin Elmer) is calibrated and checked in accordance with known procedures for temperature, displacement, force, eigendeformation, baseline and furnace temperature alignment. The films are examined using extension analysis clamps. The baseline required for the extension clamps is obtained using a very low coefficient of expansion specimen (quartz) and the CLTE precision and accuracy (dependent on post-scan baseline subtraction) is assessed using a standard material, e.g. pure aluminium foil, for which the CLTE value is well known. The specimens, selected from known axes of orientation within the original film samples, are mounted in the system using a clamp separation of approx.12 mm and subjected to an applied force of 75 mN over a 5 mm. width. The applied force is adjusted for changes in film thickness, i.e. to ensure consistent tension, and the film is not curved along the axis of analysis. Specimen lengths are normalised to the length measured at a temperature of 23° C. Specimens are cooled to 8° C., stabilised, then heated at 5° C./min from 8° C. to +240° C. The CLTE values (a) are derived from the formula:

α=ΔL/(L×(T₂−T₁))
where ΔL is the measured change in length of the specimen over the temperature range (T₂−T₁), and L is the original specimen length at 23° C. CLTE values are considered reliable up to the temperature of the Tg and so the upper limit of the quoted temperature range is just below the Tg of the test sample. The data can be plotted as a function of the % change in specimen length with temperature, normalised to 23° C.
(v) Intrinsic Viscosity (IV) was measured by melt viscometry, as follows. The rate of flow pre-dried extrudate through a calibrated die at known temperature and pressure is measured by a transducer which is linked to a computer. The computer programme calculates melt viscosity values (log₁₀ viscosity) and equivalent IVs from a regression equation determined experimentally. A plot of the IV against time in minutes is made by the computer and the degradation rate is calculated: An extrapolation of the graph to zero time gives the initial IV and equivalent melt viscosity. The die orifice diameter is 0.020 inches, with a melt temperature of 284° C. for IV up to 0.80, and 295° C. for IV>0.80.
(vi) The permeability of the composite film, and specifically its water vapour transmission rate (in g/m²/day), is measured using the calcium degradation test as described in WO-2006/097733 (see in particular FIGS. 1 and 2) and WO-02/079757-A (and also further discussed by G. Nisato, M. Kuilder, P. Bouten, L. Moro, O. Philips and N. Rutherford in Society For Information Display, Digest of Technical Papers, 2003, 550-553, the measurement method disclosure of which is incorporated herein by reference). The test substrate is cut into a square of approximately 10×10 cm square and heated at 120° C. for one hour to remove residual moisture. A thin layer of calcium (typically 100 nm) is deposited on the test substrate in an oxygen- and water-free environment in a pattern of four 28 mm discs. A glass sheet or lid is interconnected to the substrate along its edge via a substantially hermetic seal to form a closed box. The seal may be for instance glue or a solder metal. The calcium layer is initially a highly reflective metallic mirror. The structure is then placed in a humidity chamber at 60° C. and 90% relative humidity to accelerate ageing conditions. During the test, water permeating into the box reacts with the calcium to form calcium oxide or calcium hydroxide. The initial layer of calcium metal degrades to an increasingly transparent layer of calcium salt. The transparency or transmission of the layer is an indicator for the amount of water having diffused into the box. Pictures of the test cells are taken at regular intervals to follow the evolution of the samples and ascertain degradation of the cells. Automated image analysis of the photos (in this instance using Image J® software and measurement of mean grey values) yields the distribution of optical transmission of the calcium layer. Optical modelling of the transmission of calcium-calcium salt stacks enables determination of the distribution of the calcium oxide/hydroxide thickness in the cell. The thickness (z) of the degraded calcium layer at a time t during the test may be derived from mean grey values by measuring the initial mean grey value (G₀) of the layer; the mean grey value (Gₜ) of the layer at a time t during the test; and the mean grey value (G_{∞}) of the layer at 100% calcium degradation. In practice, G_{∞} is measured as the mean grey value of the test substrate in a calcium-free region between the calcium discs, and in the films exemplified in the present invention the value of G_{∞} is approximately 223. The thickness (z) of the calcium layer at a time t is then calculated from the ratio Gₜ/G_{∞} by the relationship:

Gₜ/G_{∞}=e^{-αz}
where α is a constant equal to [−ln(G₀/G_{∞})]/z₀.
Thickness can then be related to the amount of absorbed water as a function of time, yielding the effective permeation rate of the encapsulant. An example calculation of WVTR is set out below, in which an initial calcium thickness (z₀) was 100 nm, which was reduced to a thickness (z₁) of 82 nm after 768 hours.
Given that:
   Diameter of calcium deposition=2.8×10⁻² m
   Area (A) of calcium deposition=π(d/2)²=6.158×10⁻⁴ m²
   Starting thickness (z₀)=100 nm=1.0×10⁻⁷ m
   Density of deposited calcium (ρ_{Ca})=1550 kg/m³
   Molecular weight of calcium (Mr_{Ca})=40.08 g/mol
   After 768 hours thickness (z₁)=82 nm
   Loss of Ca=18%
Then:
   Volume (V_{Ca})=A.z₀=6.158×10⁻¹¹ m³
   Mass (m_{Ca})=V_{Ca}.ρ_{Ca}=1550 kg/m3×6.158×10⁻¹¹ m³=9.545×10⁻⁵ g
   Moles (mol_{Ca})=m_{Ca}/Mr_{Ca}=9.545×10⁻⁵ g/40.08 g/mol=2.381 μmol
   Ca reacted=2.381 μmol×0.18=0.429 μmol
The amount of moisture diffused to react with Ca is calculated using the reaction stoichiometry of: Ca+2H₂O→Ca(OH)₂+H₂
The moles of water required for reaction, and thus the amount of water moving through the barrier layer is therefore:
   Moles (H₂O)=2×0.429 μmol=0.857 μmol
   Mass (H₂O)=0.857×10⁻⁶ mol×18 g/mol=1.54×10⁻⁵ g
The experimental fluence is therefore:
   1.54×10⁻⁵ g over 768 hours across 6.158×10⁻⁴ m² of calcium
Converting to g/m²/day, the experimental fluence (WVTR) is therefore:
   1.54×10⁻⁵ g/6.158×10⁻⁴ m²×24/768=7.82×10⁻⁴ g/m²/day
For the purposes of the present invention, the WVTR of the composite films described herein is measured over the time period from 168 to 768 hours.
The barrier property can also be expressed in terms of the time taken for the calcium thickness to drop to 50% of its original value (referred to herein as the half-life). Preferably, the films of the present invention exhibit a half-life (in hours) of at least 250, preferably at least 500, preferably at least 750, and more preferably at least 1000, particularly in combination with a water vapour transmission rate (WVTR) of less than 10⁻³ g/m²/day.
(vii) Oxygen transmission rate is measured using ASTM D3985.
(viii) Surface Smoothness is measured using conventional non-contacting, white-light, phase-shifting interferometry techniques, which are well-known in the art, using a Wyko NT3300 surface profiler using a light source of wavelength 604 nm. With reference to the WYKO Surface Profiler Technical Reference Manual (Veeco Process Metrology, Arizona, US; June 1998; the disclosure of which is incorporated herein by reference), the characterising data obtainable using the technique include:
Averaging Parameter—Roughness Average (Ra): the arithmetic average of the absolute values of the measured height deviations within the evaluation area and measured from the mean surface.
Averaging Parameter—Root Mean Square Roughness (Rq): the root mean square average of the measured height deviations within the evaluation area and measured from the mean surface.
Extreme Value Parameter—Maximum Profile Peak Height (Rp): the height of the highest peak in the evaluation area, as measured from the mean surface.
Averaged Extreme Value Parameter—Average Maximum Profile Peak Height (Rpm): the arithmetic average value of the ten highest peaks in the evaluation area.
Extreme Peak Height Distribution: a number distribution of the values of Rp of height greater than 200 nm.
Surface Area Index: a measure of the relative flatness of a surface.
The roughness parameters and peak heights are measured relative to the average level of the sample surface area, or “mean surface”, in accordance with conventional techniques. (A polymeric film surface may not be perfectly flat, and often has gentle undulations across its surface. The mean surface is a plane that runs centrally through undulations and surface height departures, dividing the profile such that there are equal volumes above and below the mean surface.)
The surface profile analysis is conducted by scanning discrete regions of the film surface within the “field of view” of the surface profiler instrument, which is the area scanned in a single measurement. A film sample may be analysed using a discrete field of view, or by scanning successive fields of view to form an array. The analyses conducted herein utilised the full resolution of the Wyko NT3300 surface profiler, in which each field of view comprises 480×736 pixels.
For the measurement of Ra and Rq, the resolution was enhanced using an objective lens having a 50-times magnification. The resultant field of view has dimensions of 90 μm×120 μm, with a pixel size of 0.163 μm.
For the measurement of Rp and Rpm, the field of view is conveniently increased using an objective lens having a 10-times magnification in combination with a “0.5-times field of view of multiplier” to give a total magnification of 5-times. The resultant field of view has dimensions of 0.9 mm×1.2 mm, with a pixel size of 1.63 μm. Preferably Rp is less than 100 nm, more preferably less than 60 nm, more preferably less than 50 nm, more preferably less than 40 nm, more preferably less than 30 nm, and more preferably less than 20 nm.
For the measurement of Ra and Rq herein, the results of five successive scans over the same portion of the surface area are combined to give an average value. The data presented below in respect of Rp are an average value from 100 measurements. The measurements were conducted using a modulation threshold (signal:noise ratio) of 10%, i.e. data points below the threshold are identified as bad data.
The surface topography can also be analysed for the presence of extreme peaks having a height of greater than 200 nm. In this analysis, a series of measurements of Rp are taken with a pixel size of 1.63 μm over a total area of 5 cm². The results may be presented in the form of a histogram in which the data points are assigned to pre-determined ranges of peak heights, for instance wherein the histogram has equally-spaced channels along the x-axis of channel width 25 nm. The histogram may be presented in the form of a graph of peak count (y axis) versus peak height (x axis). The number of surface peaks in the range 300 to 600 nm per 5 cm² area, as determined from Rp values, may be calculated, and designated as N(300-600). The coatings used in the present invention preferably result in a reduction of N(300-600) in the film, such that the reduction F, which is the ratio of N(300-600) without and with the coating, is at least 5, preferably at least 15, and more preferably at least 30. Preferably, the N(300-600) value of the coated film is less than 50, preferably less than 35, preferably less than 20, preferably less than 10, and preferably less than 5 peaks per 5 cm² area.
The Surface Area Index is calculated from the “3-dimensional surface area” and the “lateral surface area” as follows. The “3-dimensional (3-D) surface area” of a sample area is the total exposed 3-D surface area including peaks and valleys. The “lateral surface area” is the surface area measured in the lateral direction. To calculate the 3-D surface area, four pixels with surface height are used to generate a pixel located in the centre with X, Y and Z dimensions. The four resultant triangular areas are then used to generate approximate cubic volume. This four-pixel window moves through the entire data-set. The lateral surface area is calculated by multiplying the number of pixels in the field of view by the XY size of each pixel. The surface area index is calculated by dividing the 3-D surface area by the lateral area, and is a measure of the relative flatness of a surface. An index which is very close to unity describes a very flat surface where the lateral (XY) area is very near the total 3-D area (XYZ).
A Peak-to-Valley value, referred to herein as “PV₉₅”, may be obtained from the frequency distribution of positive and negative surface heights as a function of surface height referenced to the mean surface plane. The value PV₉₅ is the peak-to-valley height difference which envelops 95% of the peak-to-valley surface height data in the distribution curve by omitting the highest and lowest 2.5% of datapoints. The PV₉₅ parameter provides a statistically significant measure of the overall peak-to-valley spread of surface heights.

The invention is further illustrated by the following examples. The examples are not intended to limit the invention as described above. Modification of detail may be made without departing from the scope of the invention.

### EXAMPLES

I: Preparation of Planarised Substrates

A polymer composition comprising PEN was extruded and cast onto a hot rotating polished drum. The film was then fed to a forward draw unit where it was stretched over a series of temperature-controlled rollers in the direction of extrusion to approximately 3.3 times its original dimensions. The draw temperature was approximately 130° C. The film was then treated on both surfaces with an adhesion-promoting primer coating. The film was then passed into a stenter oven at a temperature of 135° C. where the film was stretched in the sideways direction to approximately 3.4 times its original dimensions. The biaxially stretched film was then heat-set at temperatures up to 235° C. by conventional means, allowing the transverse dimensions of the web to be reduced by 4%, before being cooled and would onto reels. The total thickness was 125 μm. The heat-set biaxially stretched film was then unwound and then further heat-stabilised in a roll-to-roll process by passing the film through an additional set of ovens, of which the maximum temperature was 190° C. The film was unsupported at its edges and transported through the ovens under a low line tension, allowing it to relax and stabilize further. The biaxially stretched, heat-set, surface-primed and offline-stabilized film is referred to herein as Control 1. The film was then unwound and one side was further modified by coating with a planarising coating composition, as detailed in Examples 1 to 7 below.

### Example 1

The coating composition was of the inorganic type described herein and previously disclosed in WO-A-03/087247. It was prepared before application by the following steps:

(i) 737 grams of methyltrimethoxysilane (OSi Specialities) was added to 80 grams of 3-glycidoxypropyl trimethoxysilane (obtained from Aldrich Chemical Company) and stirred at room temperature for 5 minutes.

(ii) 250 grams of propan-2-ol (Aldrich Chemical Company) was mixed with 1000 grams of Ludox® LS colloidal silica (Grace Davison Company) and 75 grams of a 10% solution of aqueous acetic acid (Aldrich Chemical Company) for 15 minutes.

(iii) The methoxysilane mixture in (i) was then added to the acidified Ludox and propan-2-ol mixture in (ii) and stirred for 5 hours.

(iv) The solution was then diluted with a solvent mixture containing 1262 grams of propan-2-ol and 756 grams of water and stirred for 40 hours whereupon it was ready for coating.

The final pH of the composition was 6.4

The coating was applied to one surface of the polyester film, which was then heated, cooled and rewound. The dry thickness of the final planarising coating was 2 μm.

### Example 2

An organic coating composition comprising a mixture of monomeric and polymeric acrylates (including methylmethacrylate and ethylacrylate) and a photoinitiator (Irgacure™ 2959; Ciba) in a solvent of methyl ethyl ketone (2-butanone) was prepared at 26.5 wt % solids (of which about 1% of these solids is the photoinitiator) to a viscosity of about 1.22 cP (centipoise). The coating was applied to the substrate dried at 80° C. and then cured by UV-radiation.

### Example 3

A hybrid organic/inorganic coating composition comprising acrylate monomers and silica particles in MEK solvent was prepared to 10% solids and a viscosity of about 1.7 cP. The coating was applied and then cured immediately by UV-radiation.

### Example 4

A coating comprising polyethylene imine (Sigma Aldrich code 181978-8; average molecular weight Mw of about 750,000) and a crosslinker (Cymel™ 385) in water at approximately 5% by weight PEI solids, was coated onto the substrate and thermally cured at 180° C.

### Example 5

A thermally-curable coating composition comprising epoxy resin in combination with silica particles present at a concentration of about 41% b_{y} weight of the solids of the coating composition, which in turn comprises about 10% by weight total solids in an alcoholic solution (a mixed solvent system of isopropanol, n-butanol, ethanol and cyclohexanone). The composition is stirred for 6 hours at room temperature, coated onto the substrate and then thermally cured at 180° C.

### Example 6

A thermally-curable coating comprising polyester (TPE 62C; Takemoto Oil and Fat Company, Japan), a crosslinker (Cymel™ 385; Cytec) in aqueous solvent (8% total solids, of which 86% is the polyester) was coated onto the PEN substrate and thermally cured at 180° C.

### Example 7

A coating composition comprising PVOH (Airvol™ 24-203; Air Products) at 24% by weight of the coating composition, a surfactant (Caflon™ NP10; Uniqema) at 10% by weight of the coating composition and varying amounts (0 9, 17, 24 and 29% by weight of the PVOH present in the composition) of crosslinking agent (Cymel™ 350; American Cyanamid), in aqueous solvent, was coated onto the PEN substrate and thermally cured at 180° C.

### Examples 8 to 14

The coating compositions of Examples 1 to 7 were coated onto a PET substrate (Melinex® ST506; Dupont Teijin Films) having a thickness of 125 μm.

The planarised surfaces of the Examples exhibited an Ra value of less than 0.7 nm and an Rq value of less than 0.9 nm, measured as described herein. The (unplanarised) surface of Control 1 exhibited an Ra of 1.86 nm and an Rq of 2.96 nm.

II: Deposition of Gas-Barrier Layers by ALD

The unplanarised and planarised substrates described above are coated on one side with an Al₂O₃ barrier layer deposited by atomic layer deposition, using trimethylaluminium as the precursor for aluminium and ozone as the oxidant. The samples were prepared by cutting 100 mm×100 mm sections from a roll of the polymeric film using a scalpel blade in a clean air station inside a clean room. The samples were mounted on an aluminium carrier plate (so and that only one side was coated) and loaded into an Oxford Instruments FlexAL® tool, and the chamber evacuated. The trimethylaluminum precursor is admitted to the chamber at a pressure of 100 millitorr for approximately 2 seconds. The chamber is then purged with argon for approximately 2 seconds. The oxidant is then admitted to the chamber at 100 millitorr for approximately 2 seconds. Finally, the oxidant is purged with argon for approximately 2 seconds. The substrate temperature during deposition is 120° C. for both PEN and PET substrates. Each deposited layer is about 0.1 nm thick and the deposition process is repeated to obtain a total coating thickness of approximately 40 nm.

The resultant composite films are transparent and show high gas-barrier properties. Eight samples of each ALD-coated Example or Control film were analysed using the test methods described herein. The results for Examples 1 and 3 and Control 1 are presented in Table 1 below. The half-life is the lifetime in hours for a 50% reduction in thickness across a continuous calcium layer in the calcium test described herein. The WVTR value may be calculated on the basis of the amount of water transmitted (cumulative) over the defined time period through a continuous calcium layer in the calcium test described herein.

TABLE 1

| SAMPLE | Ra (nm) | Rq (nm) | Half-life (hours) |
|---|---|---|---|
| Control 1 | 1.86 | 2.96 | 166 |
| Example 1 | 0.49 | 0.63 | 547 |
| Example 3 | 0.31 | 0.43 | >768 |

Unexpectedly, the ALD-coated but unplanarised film of Control 1 showed significantly inferior performance, despite the teaching of the prior art that the ALD technique alone provides a conformable pinhole-free barrier layer over a textured surface. Instead, the present inventors have found that the additional use of a planarising coating prior to deposition of the ALD-layer unexpectedly provides further improvements in the gas-barrier performance of the substrate.

1. A composite film comprising a polymeric substrate and a planarising coating layer wherein the surface of the planarised substrate exhibits an Ra value of less than 0.7 nm and/or an Rq value of less than 0.9 nm, and wherein the composite film further comprises a gas-permeation barrier deposited by atomic layer deposition on a planarised surface of the substrate.

2. A composite film according to claim 1 wherein the polymeric substrate is biaxially oriented.

3. A composite film according to claim 1 or 2 wherein said polymeric substrate is a heat-stabilised, heat-set, biaxially oriented substrate.

4. A composite film according to any preceding claim wherein the polymeric substrate is a polyester substrate.

5. A composite film according to claim 4 wherein the polyester is poly(ethylene terephthalate) or poly(ethylene naphthalate).

6. A composite film according to any preceding claim wherein said polymeric substrate exhibits a coefficient of linear thermal expansion (CLTE) within the temperature range from 23° C. to the glass transition temperature of the substrate of less than 40×10⁻⁶/° C.

7. A composite film according to any preceding claim wherein said polymeric substrate exhibits a shrinkage at 30 mins at 120° C., of no more than 0.05%.

8. A composite film according to any preceding claim wherein said polymeric substrate exhibits a shrinkage at 30mins at 150° C. of no more than 0.05%.

9. A composite film according to any preceding claim wherein said polymeric substrate exhibits a shrinkage at 10 mins at 200° C. of less than 2%.

10. A composite film according to any preceding claim wherein said polymeric substrate is optically clear.

11. A composite film according to any preceding claim wherein said planarising coating layer is derived from a composition selected from:
(i) an organic coating composition comprising a low molecular weight reactive diluent; an unsaturated oligomer; a solvent; and a photoinitiator;
(ii) an organic/inorganic hybrid coating composition comprising a low molecular weight reactive component and/or an unsaturated oligomeric component; inorganic particles, and optionally further comprising a solvent and/or photoinitiator;
(iii) a predominantly inorganic coating composition comprising inorganic particles contained in a polymerisable predominantly inorganic matrix; and
(iv) a composition comprising a cross-linkable organic polymer selected from polyethylene imine (PEI), polyester, polvinylalcohol (PVOH), polyamide, polythiol and polyacrylic acid, and a cross-linking agent.

12. A composite film according to any preceding claim wherein said planarising coating layer is derived from a composition selected from an organic/inorganic hybrid coating derived from a coating composition comprising a low molecular weight reactive component and/or an unsaturated oligomeric component; a solvent; and inorganic particles, and optionally further comprising a photoinitiator.

13. A composite film according to claim 12 wherein said inorganic particles have an average particle diameter of from about 0.005 to about 3 μm.

14. A composite film according to claim 12 or 13 wherein said inorganic particles are present in an amount of from about 5% to about 60% by weight of the solids components of the coating composition.

15. A composite film according to claim 12, 13 or 14 wherein said inorganic particles are selected from silica and metal oxides.

16. A composite film according to any of claims 12 to 15 wherein said composition is UV-curable.

17. A composite film according to any of claims 11 to 16 wherein said low molecular weight reactive component is selected from monomeric acrylates and/or said unsaturated oligomeric component is selected from acrylates, urethane acrylates, polyether acrylates, epoxy acrylates and polyester acrylates.

18. A composite film according to any preceding claim wherein said planarising coating is derived from a UV-curable composition comprising monomeric acrylates, silica particles and a photoinitiator.

19. A composite film according to any of claims 1 to 11 wherein the planarising coating layer comprises inorganic particles in a polysiloxane matrix.

20. A composite film according to any of claims 1 to 11 wherein the planarising coating layer is derived from a coating composition comprising:
(a) from about 5 to about 50 weight percent solids, the solids comprising from about 10 to about 70 weight percent silica and from about 90 to about 30 weight percent of a partially polymerized organic silanol of the general formula RSi(OH)₃, wherein R is selected from methyl and up to about 40% of a group selected from the group consisting of vinyl, phenyl, gamma-glycidoxypropyl, and gamma-methacryloxypropyl, and
(b) from about 95 to about 50 weight percent solvent, the solvent comprising from about 10 to about 90 weight percent water and from about 90 to about 10 weight percent lower aliphatic alcohol,
particularly wherein the coating composition has a pH of from about 3.0 to about 8.0.

21. A composite film according to any of claims 1 to 11 wherein the planarising coating layer is derived from a composition comprising a UV-curable mixture of monomeric and oligomeric acrylates in a solvent, and further comprising a photoinitiator.

22. A composite film according to any preceding claim wherein said planarising coating layer has a dry thickness of from 1 to 20 microns.

23. A composite film according to any preceding claim wherein the composite film exhibits a water vapour transmission rate less than 10⁻³ g/m²/day and/or an oxygen transmission rate less than 10⁻³/mL/m²/day.

24. A composite film according to any preceding claim wherein the composite film exhibits a half-life of at least 250 hours in the calcium-test.

25. A composite film according to any preceding claim wherein the gas-permeation barrier layer comprises a material selected from SiO₂, Al₂O₃, ZnO, ZnS, HfO₂, HfON, AlN, and Si₃N₄.

26. A composite film according to any preceding claim wherein the gas-permeation barrier layer comprises Al₂O₃.

27. A composite film according to any preceding claim wherein the thickness of the gas-permeation barrier layer is from 2 to 100 nm.

28. A composite film according to any preceding claim further comprising an electrode layer disposed on the surface of a gas-permeation barrier layer.

29. An electronic device comprising a composite film as defined in any of claims 1 to 28 and further comprising electronic circuitry.

30. An electronic device according to claim 29 which is an electronic display device, a photovoltaic cell or a semiconductor device.

31. An electronic device according to claim 29 or 30 which is flexible.

32. A process for the manufacture of a composite film which comprises the step of disposing by atomic layer deposition a gas-permeation barrier layer on the or each planarised surface of a planarised coated polymeric substrate, the planarised coated surface of which exhibits an Ra value of less than 0.7 nm, and/or an Rq value of less than 0 9 nm.

33. A process according to claim 32 wherein the polymeric substrate is provided by the following steps:
(a) forming a polymeric substrate layer;
(b) stretching the substrate layer in at least one direction;
(c) heat-setting under dimensional restraint at a tension in the range of about 19 to about 75 kg/m of film width, at a temperature above the glass transition temperature of the polymer of the substrate layer but below the melting temperature thereof; and
(d) heat-stabilising the film at a temperature above the glass transition temperature of the polymer of the substrate layer but below the melting temperature thereof

34. A process according to claim 32 or 33 wherein the planarised coated polymeric substrate is provided by disposing on the or each surface of a polymeric substrate a planarising coating composition such that the planarised coated surface of the polymeric substrate exhibits an Ra value of less than 0.7 nm, and/or an Rq value of less than 0.9 nm.

35. A process according to claim 32, 33 or 34 wherein the composite film is as defined in any of claims 1 to 28.
